(19) United States
(12) Patent Application Publication
(10) Pub. No.: US 2019/0056183 A1
(43) Pub. Date: Feb. 21, 2019

(54) FIXING STRUCTURE AND HEAT DISSIPATION DEVICE THEREWITH

(71) Applicant: CHAMP TECH OPTICAL (FOSHAN) CORPORATION, Foshan (CN)

(72) Inventors: JING ZHANG, Foshan (CN); BO HU, Foshan (CN)

(21) Appl. No.: 15/684,475

(22) Filed: Aug. 23, 2017

(30) Foreign Application Priority Data
Aug. 15, 2017 (CN) 201710697126.2

(51) Int. Cl. F28F 9/26; H01L 23/40

(52) U.S. Cl. CPC F28F 9/26; F28F 2275/085; H01L 23/4093

(57) ABSTRACT

A fixing structure for a heat-dissipating device includes a body with a shape of hollow cylinder, at least one outer hook, and at least one inner hook. The at least one outer hook is located on the outer surface of the body. The at least one inner hook is located on the inner surface of the body.

### FIELD

The subject matter relates to heat dissipation, especially relates to a fixing structure and a heat dissipation device with the fixing structure.

### BACKGROUND

Heat generating components, such as central processing units (CPUs), generate heat when in operation. In an electronic device that uses the CPU, a heat dissipation device can be used to dissipate heat. The heat dissipation device usually includes a base plate. Corners of base plate are fixed to the electronic device by screws, but the screws can become loose. Improvements in the art is preferred.

### BRIEF DESCRIPTION OF THE DRAWINGS

Implementations of the present disclosure will now be described, by way of example only, with reference to the attached figure, wherein:

FIG. 1 is a diagram of a heat dissipation device of an exemplary embodiment.

FIG. 2 is an exploded view of the heat dissipation device of FIG. 1.

FIG. 3 is a diagram of a fixing structure of the heat dissipation device of FIG. 2.

FIG. 4 is similar to FIG. 3, but showing the fixing structure from another angle.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the exemplary embodiments described herein. However, it will be understood by those of ordinary skill in the art that the exemplary embodiments described herein can be practiced without these specific details.

In other instances, methods, procedures, and components have not been described in detail so as not to obscure the related relevant feature being described. Also, the description is not to be considered as limiting the scope of the exemplary embodiments described herein. The drawings are not necessarily to scale and the proportions of certain parts may be exaggerated to better illustrate details and features of the present disclosure.

One definition that applies throughout this disclosure will now be presented.

The term “substantially” is defined to be essentially conforming to the particular dimension, shape, or other feature that the term modifies, such that the component need not be exact. For example, “substantially rectangular” means that the object resembles a rectangle, but can have one or more deviations from a true rectangle.

The term “comprising,” when utilized, means “including, but not necessarily limited to”; it specifically indicates open-ended inclusion or membership in the so-described combination, assembly, series, and the like.

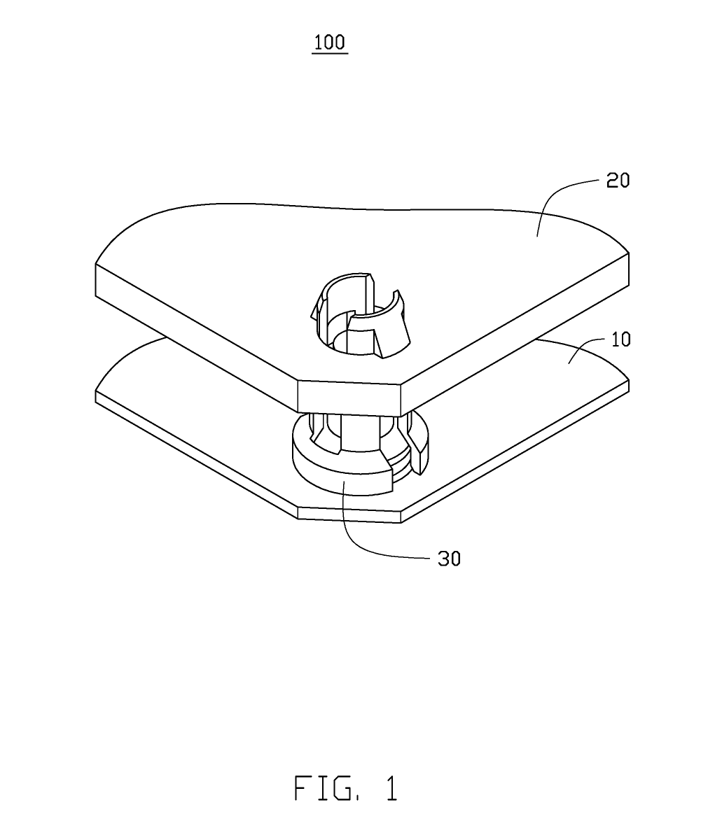

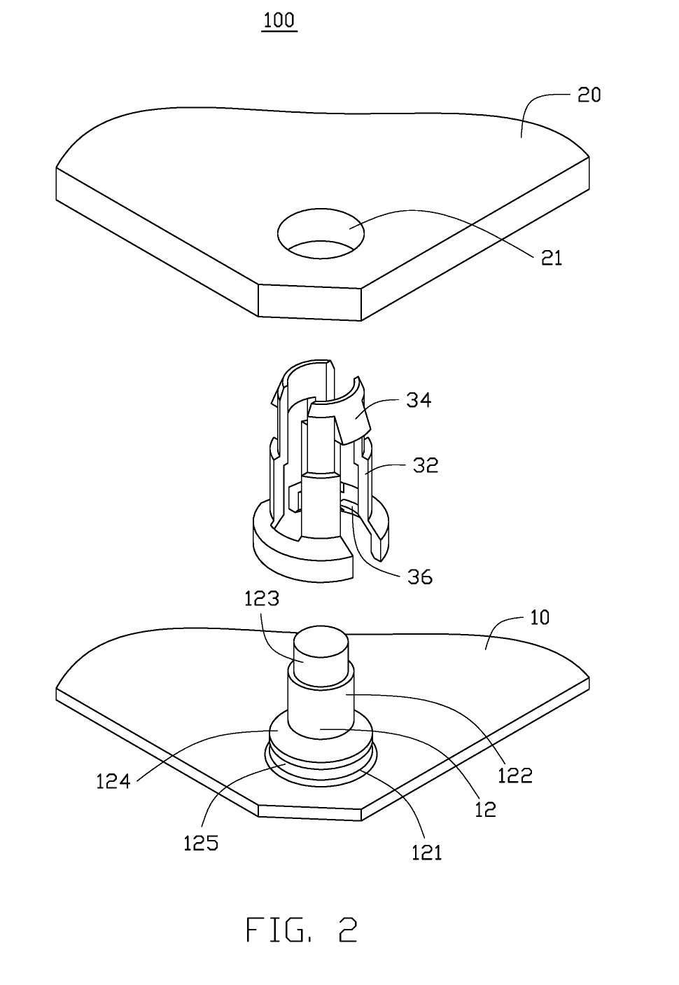

Referring to FIGS. 1 to 2, a heat dissipation device 100 comprises a base 10, a cooling plate 20, and a fixing structure 30. The cooling plate 20 is fixed on the base 10 through the fixing structure 30.

Referring to FIG. 2, the base 10 comprises a number of screw studs 12. The screw studs 12 are positioned on the base 10. In the exemplary embodiment, the screw studs 12 are positioned at diagonally opposite corners of the base 10 (FIGS. 1 and 2 show only one screw stud 12 at one corner for simplicity). The screw studs 12 are substantially cylindrical.

In the exemplary embodiment, the screw stud 12 comprises a first cylinder 121, a second cylinder 122, and a third cylinder 123. The first cylinder 121 is positioned on the base 10. The second cylinder 122 is connected between the first cylinder body 121 and the third cylinder body 123. The third cylinder 123 is away from the base 10. The diameter of the first cylinder 121 is greater than the diameter of the second cylinder 122. The diameter of the second cylinder 122 is greater than the diameter of the third cylinder 123. A ring-shaped flange 124 protrudes from an outer circumferential surface of an end of the first cylinder 121 adjacent to the second cylinder 122. The base 10, the first cylinder 121, and the ring-shaped flange 124 cooperatively define an annular groove 125.

A plurality of mounting holes 21 is defined on the cooling plate 20. The mounting holes 21 are positioned at opposite ends along a diagonal of the cooling plate 20 (FIGS. 1 and 2 shows only one mounting hole 12 at one corner for simplicity).

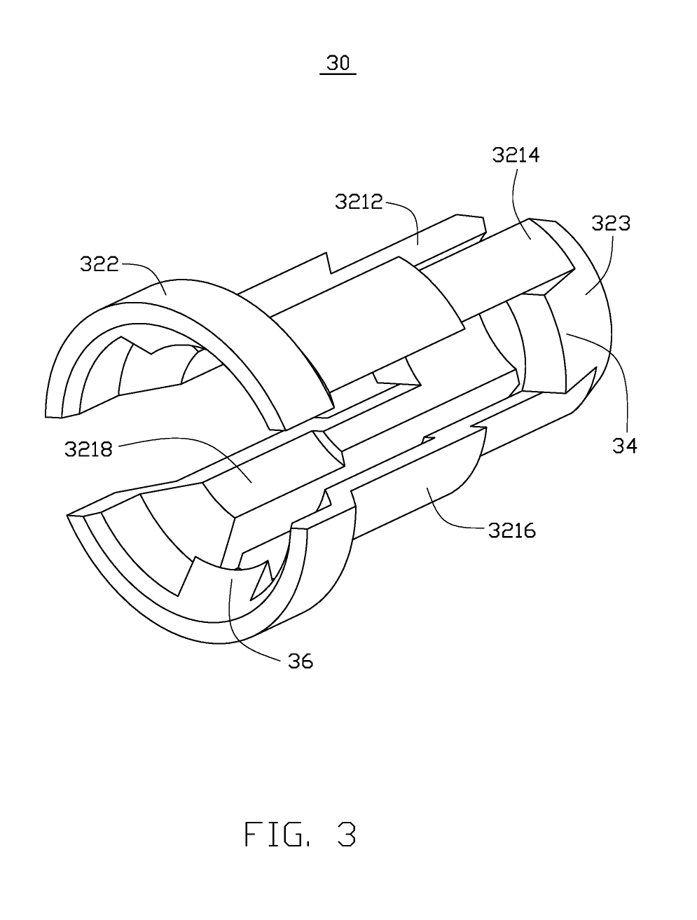

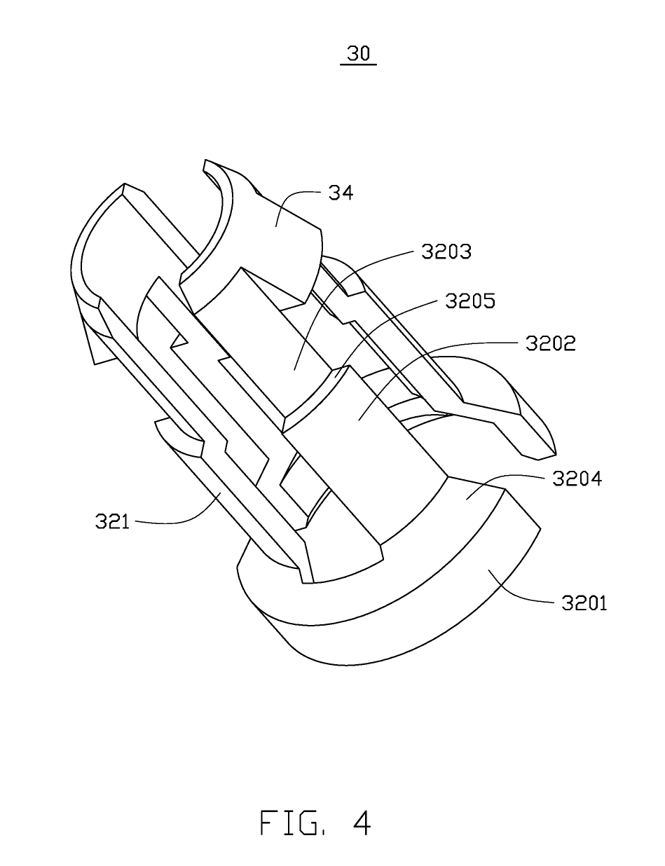

Referring to FIGS. 3 to 4, the fixing structure 30 comprises a body 32, at least one outer hook 34, and at least one inner hook 36. In the exemplary embodiment, the fixing structure 30 comprises two outer hooks 34 and two inner hooks 36.

The body 32 is hollow and cylindrical. In the exemplary embodiment, the body 32 comprises four curved plates 321, two first connecting plates 322, and two second connecting plates 323. Each of the two adjacent curved plates 321 are spaced from each other by a same distance. The four curved plates 321 comprise a first curved plate 3212, a second curved plate 3214, a third curved plate 3216, and a fourth curved plate 3218. The first curved plate 3212, the second curved plate 3214, the third curved plate 3216, and the fourth curved plate 3218 are orderly positioned on an imaginary circle. The two first connecting plates 322 are located at one end of the four curved plates 321. One first connecting plate 322 is connected between the first curved plate 3212 and the second curved plate 3214, and the other first connecting plate 322 is connected between the third curved plate 3216 and the fourth curved plate 3218. The two second connecting plates 323 are located at the other end of the four curved plates 321 opposite to the two first connecting plates 322. One second connecting plate 323 is connected between the first curved plate 3212 and the third curved plate 3218, and the other second connecting plate 323 is connected between the second curved plate 3214 and the fourth curved plate 3216. In the exemplary embodiment, the first connecting plates 322 are located near the base 10, and the second connecting plates 323 are located away from the base 10. The first connecting plates 322 protrude away from a center axis of the curved plates 321. The second connecting plates 323 are recessed towards the center axis of the curved plates 321.

In the exemplary embodiment, each curved plate 321 comprises a first portion 3201, a second portion 3202, and a third portion 3203. The first connecting plates 322 are connected to the first portion 3201. The second connecting plates 323 are connected to the third portion 3203. The second portion 3202 connects between the first portion 3201 and the third portion 3203. The first portion 3201, the second portion 3202, and the third portion 3203 are curved sheets. A radius of curvature of the first portion 3201 is greater than a radius of curvature of the second portion 3202. The radius of curvature of the second portion 3202 is greater than the radius of curvature of the third portion 3203. In the exemplary embodiment, an annular surface 3204 is formed between the first portion 3201 and the second portion 3202, and an annular step surface 3205 is formed between the second portion 3202 and the third portion 3203.

The two outer hooks 34 are located at opposite sides of the outer surface of the body 32. The two outer hooks 34 protrude from the two second connecting plates 323 toward the first portion 3201. The inner surface of the outer hook 34 is coplanar with the outer surface of the second connecting plate 323. The outer surface of the outer hook 34 is inclined away from the central axis of the body 32. A thickness of the outer hook 34 gradually increases along the direction perpendicular to the central axis of the body 32. The outer surfaces of the two outer hooks 34 are inclined to the central axis of the body 32 by a same angle, and the angle is in the range of 0 to 90 degrees. In at least one exemplary embodiment, the angle is between 15 degrees and 30 degrees.

The two inner hooks 36 are located at opposite sides of the inner surface of the body 32. The two inner hooks 36 are positioned on the two first connecting plates 322. The two inner hooks 36 extend from the first portion 3201 towards the third portion 3203. The inner side surface of the inner hook 36 is coplanar with the inner surface of the first connecting plate 322, and the outer surface of the inner hook 36 is inclined to the central axis of the body 32. A thickness of the inner hook 36 is gradually increased along the direction perpendicular to the central axis of the body 32. The two inner hooks 36 and the outer hooks 34 may be integrally formed with the body 32.

The outer surfaces of the two inner hooks 36 are inclined to the central axis in the body 32 by a same angle. The angle is in the range of 0 to 90 degrees. In at least one exemplary embodiment, the angle is between 15 degrees and 30 degrees.

A lower end of the first portion 3201 abuts the base 10. The first portion 3201 matches the first cylinder 121 in shape. The two inner hooks 36 are engaged in the annular groove 125 so that the fixing structure 30 cannot easily fall off from the screw stud 12. The second portion 3202 matches the second cylinder 122 in shape. The third portion 3203 matches the third cylinder 123 in shape. The body 32 wraps around the screw stud 12. The cooling plate 20 wraps around the outer surface of the third portion 3203 through the mounting hole 21, and is fitted between the two outer hooks 34 and the second portion 3202. The two outer hooks 34 can snap onto the surface of the cooling plate 20 to prevent the cooling plate 20 from falling off from the base 10.

In assembly, the base 10 is placed on a horizontal surface (not shown). The fixing structures 30 are mounted on the screw studs 12. The first portion 3201 is engaged with the first cylinder 121. The two inner hooks 36 are engaged in the annular groove 125. The second portion 3202 is engaged with the second cylinder 122. The third portion 3203 is engaged with the third cylinder 123. The cooling plate 20 is mounted on the fixing structure 30. A diameter of the mounting hole 21 is larger than the diameter of the third portion 3203, and is smaller than the diameter of the outermost edge of the two outer hooks 34. The upper and lower surfaces of the cooling plate 20 abut the two outer hooks 34 and the annular step surface 3204. At this time, the cooling plate 20 is positioned at the outer edge of the third portion 3203 and is fitted between the two outer hooks 34 and the second portion 3202. The two outer hooks 34 can snap onto the surface of the cooling plate 20 to prevent it from falling off from the base 10.

For disassembly, the two outer hooks 34 are pressed towards the body 32, and the cooling plate 20 is lifted to cause the cooling plate 20 to move out of the fixing structure 30. The two first portions 3201 are pulled away from each other, and the fixing structure 30 can be moved upwards and separated from the screw stud 12 of the base 12.

Since the inner hooks 36 can engage with the annular groove 125, the fixing structure 30 does not easily fall off from the screw stud 12. Furthermore, the outer hooks 34 can snap onto the surface the cooling plate 20, thus preventing the cooling plate 20 from falling off from the screw stud 12.

The embodiment shown and described above is only an example. Many details are often found in the art such as the other features. Therefore, many such details are neither shown nor described. Even though numerous characteristics and advantages of the present disclosure have been set forth in the foregoing description, together with details of the structure and function of the present disclosure, the disclosure is illustrative only, and changes may be made in the detail, especially in matters of shape, size, and arrangement of the parts within the principles of the present disclosure, up to and including the full extent established by the broad general meaning of the terms used in the claims. It will therefore be appreciated that the embodiments described above may be modified within the scope of the claims.

What is claimed is:

1. A fixing structure comprising:
a body comprising an outer surface and an inner surface facing away from the outer surface;
at least one outer hook, the at least one outer hook on the outer surface of the body; and
at least one inner hook, the at least one inner hook on the inner surface of the body.

2. The fixing structure of claim 1, wherein the body is a hollow cylinder, the body comprises at least three curved plates, at least one first connecting plate, and at least one second connecting plates, each of the two adjacent curved plates are spaced from each other by a same distance, each first connecting plate is connected between two adjacent curved plates and positioned at one end of the two curved plates, and each second connecting plate is connected between two adjacent curved plates and positioned at the other end of the curved plate.

3. The fixing structure of claim 2, wherein the at least one outer hook is at an outer surface of the at least one first connecting plate, the at least one inner hook is at an inner surface of the at least one second connecting plate.

4. The fixing structure of claim 3, wherein the first connecting plate protrudes away from a center axis of the curved plates, an inner surface of the inner hook is coplanar with an inner surface of the first connecting plate, an outer surface of the inner hook is inclined to a central axis of the body, a thickness of the inner hook gradually increases along a direction perpendicular to the central axis of the body.

5. The fixing structure of claim 3, wherein the second connecting plate is recessed towards a center axis of the curved plate, an inner surface of the outer hook is coplanar with an outer surface of the second connecting plate, an outer surface of the outer hook is inclined away from the central axis of the body, a thickness of the outer hook gradually increases along a direction perpendicular to the central axis of the body.

6. The fixing structure of claim 2, wherein each curved plate comprise a first portion, a second portion, and a third portion, the first connecting plate is connected to the first portion, the second connecting plates is connected to the third portion, the second portion connects between the first portion and the third portion, a radius of curvature of the first portion is greater than a radius of curvature of the second portion, a radius of curvature of the second portion is greater than the radius of curvature of the third portion.

7. The fixing structure of claim 2, wherein the body comprises four curved plates, two first connecting plates, and two second connecting plates, the two first connecting plates are at one end of the four curved plates, the two second connecting plates are at the other end of the four curved plates opposite to the two first connecting plates, one first connecting plate is connected between the first curved plate and the second curved plate, and the other first connecting plate is connected between the third curved plate and the fourth curved plate, one second connecting plate is connected between the first curved plate and the third curved plate, and the other second connecting plate is connected between the second curved plate and the fourth curved plate.

8. A heat dissipation device comprising:
a base;
a cooling plate; and
a plurality of fixing structure, each of the plurality of fixing structures comprising:
a body comprising an outer surface and an inner surface facing away from the outer surface;
at least one outer hook, the at least one outer hook on the outer surface of the body; and
at least one inner hook, the at least one inner hook on the inner surface of the body,
wherein the base and the cooling plate are fixed through the plurality of fixing structures, the base comprises at least one screw studs, an annular groove is defined at a bottom of each screw stud, the at least one inner hook is engaged with the annular groove, a plurality of mounting holes are defined in the cooling plate, a diameter of the mounting holes is greater than a diameter of the body, and smaller than a diameter of an outermost edge of the at least one outer hook, the body of each of the plurality of fixing structures passes through one of the plurality of mounting holes, the cooling plate is located between the two outer hooks and the base.

9. The heat dissipation device of claim 8, wherein the body is a hollow cylinder, the body comprises at least three curved plates, at least one first connecting plate, and at least one second connecting plates, each of the two adjacent curved plates are spaced from each other by a same distance, each first connecting plate is connected between two adjacent curved plates and positioned at one end of the two curved plates, and each second connecting plate is connected between two adjacent curved plates and positioned at the other end of the curved plate.

10. The heat dissipation device of claim 9, wherein the at least one outer hook is at an outer surface of the at least one first connecting plate, the at least one inner hook is at an inner surface of the at least one second connecting plate.

11. The heat dissipation device of claim 8, wherein each curved plate comprise a first portion, a second portion, and a third portion, the first connecting plate is connected to the first portion, the second connecting plates is connected to the third portion, the second portion connects between the first portion and the third portion, a radius of curvature of the first portion is greater than a radius of curvature of the second portion, a radius of curvature of the second portion is greater than the radius of curvature of the third portion.

12. The heat dissipation device of claim 11, wherein the screw stud comprises a first cylinder, a second cylinder, and a third cylinder, the diameter of the first cylinder is greater than the diameter of the second cylinder, the diameter of the second cylinder is greater than the diameter of the third cylinder, the first portion is engaged with the first cylinder, the second portion is engaged with the second cylinder, the third portion is engaged with the third cylinder.
